(19) United States
(12) Patent Application Publication
(10) Pub. No.: US 2023/0238779 A1
(43) Pub. Date: Jul. 27, 2023

(54) DOT-PROJECTING OPTICAL DEVICE

(71) Applicant: Lumentum Operations LLC, San Jose, CA (US)

(72) Inventors: John Michael MILLER, Ottawa (CA); Lijun ZHU, Pleasanton, CA (US); Kevin WANG, Fremont, CA (US); Matthew Glenn PETERS, Menlo Park, CA (US)

(21) Appl. No.: 17/657,517

(22) Filed: Mar. 31, 2022

Related U.S. Application Data
(60) Provisional application No. 63/267,219, filed on Jan. 27, 2022.

(51) Int. Cl. H01S 5/42; G02B 5/18; G02B 27/30; G02B 27/42

(52) U.S. Cl. CPC H01S 5/423; G02B 5/1819; G02B 27/30; G02B 27/4233; H01S 5/18311

(57) ABSTRACT

In some implementations, an optical device includes a two-zone vertical cavity surface emitting laser (VCSEL) with a set of emission zones configured to emit structured light forming a set of dots; a single-element collimating lens aligned to the two-zone VCSEL; and a tiling diffractive optical element (DOE) aligned to the single-element collimating lens, wherein the tiling DOE comprises a set of tile segments aligned to the set of emission zones, and wherein a tile segment, of the set of tile segments, is configured to project, from the set of emission zones toward portions of a target, the structured light forming the set of dots.

### CROSS-REFERENCE TO RELATED APPLICATION

This Patent application claims priority to U.S. Provisional Patent Application No. 63/267,219, filed on Jan. 27, 2022, and entitled “MULTI-ZONE VERTICAL CAVITY SURFACE EMITTING LASER DOT PROJECTOR.” The disclosure of the prior Application is considered part of and is incorporated by reference into this Patent Application.

### TECHNICAL FIELD

The present disclosure relates generally to optical devices and to a multi-zone vertical cavity surface emitting laser (VCSEL) dot projector.

### BACKGROUND

A structured light emitter system, such as a dot projector, may include a VCSEL. The dot projector may include one or more collimating elements (e.g., lenses) to collimate light emitted by the VCSEL. The structured light emitter system may emit structured light, which may include a set of dots. A receiver may detect reflections of the structured light, thereby enabling use of the structured light for gesture recognition, three-dimensional (3D) sensing, or time-of-flight (ToF) determinations, among other examples.

### SUMMARY

In some implementations, an optical device includes a two-zone vertical cavity surface emitting laser (VCSEL) with a set of emission zones configured to emit structured light forming a set of dots; a single-element collimating lens aligned to the two-zone VCSEL; and a tiling diffractive optical element (DOE) aligned to the single-element collimating lens, wherein the tiling DOE comprises a set of tile segments aligned to the set of emission zones, and wherein a tile segment, of the set of tile segments, is configured to project, from the set of emission zones toward portions of a target, the structured light forming the set of dots.

In some implementations, an optical device includes a first VCSEL with a first emission zone configured to emit first structured light forming a first set of dots; a second VCSEL with a second emission zone configured to emit second structured light forming a second set of dots; a single-element collimating lens aligned to the first VCSEL and the second VCSEL; and a tiling DOE aligned to the single-element collimating lens, wherein the tiling DOE comprises a set of tile segments aligned to the first emission zone to form a first set of projections of the first set of dots and aligned to the second emission zone to form a second set of projections of the second set of dots.

In some implementations, an optical device includes at least one VCSEL, wherein the at least one VCSEL comprises a set of emission zones, wherein an emission zone, of the set of emission zones, is configured to emit structured light forming a set of dots; at least one single-element collimating lens aligned to the set of emission zones of the at least one VCSEL; and a tiling DOE aligned to the at least one single-element collimating lens, wherein the tiling DOE comprises a set of tile segments aligned to the set of emission zones, and wherein a tile segment, of the set of tile segments, is configured to project the structured light forming the sets of dots from the set of emission zones toward portions of a target.

### BRIEF DESCRIPTION OF THE DRAWINGS

FIGS. 1A and 1B is a diagram of an example emitter described herein.

FIGS. 2A-2C are diagrams of an example optical device described herein.

FIG. 3 is a diagram of an example optical device described herein.

FIGS. 4A-4D are diagrams of electro-optical characteristics associated with an optical device described herein.

FIG. 5 is a flowchart of an example process relating to using an optical device described herein.

### DETAILED DESCRIPTION

The following detailed description of example implementations refers to the accompanying drawings. The same reference numbers in different drawings may identify the same or similar elements.

As described above, a structured light emitter system may include a vertical cavity surface emitting laser (VCSEL) or VCSEL array to project a grid of dots toward a target, which may enable gesture recognition, three-dimensional (3D) sensing, or time-of-flight (ToF) determinations, among other uses. In this case, the VCSEL may project a set of dots toward a far-field target (e.g., a flat screen or a curved screen) and a receiver may capture information regarding the set of dots. A sensing system may use the captured information to determine, for example, a range to the far-field target. A fill factor can refer to a total area of dots as a ratio of a total field of illumination (FOI). When the fill factor exceeds a threshold (e.g., a size of the projected dots is too large, such as can occur when some optics are used to control projection from a VCSEL), there can be a negative impact to a resolution of the VCSEL. To achieve a fill factor that is less than a threshold, an optical aperture of the VCSEL can be reduced in size. However, reducing a size of the optical aperture may limit an available power for the structured light. Accordingly, it may be desirable for an emitter to achieve a fill factor less than a threshold without a reduction in a size of an optical aperture of the emitter.

Some implementations described herein enable projection of higher quantities of dots without exceeding a fill factor threshold. For example, an optical device may include a VCSEL, a collimating lens, and a tiling diffractive optical element (DOE) to project structured light toward a target. In this case, the tiling DOE is aligned to the VCSEL and the collimating lens to project multiple emission zones of dots toward the target. In this way, an optical device can project, for example, 1000 dots of structured light with a fill factor of, for example, less than 10% or less than 5%, among other examples. In this way, the optical device enables improved sensing using structured light relative to other types of dot projectors.

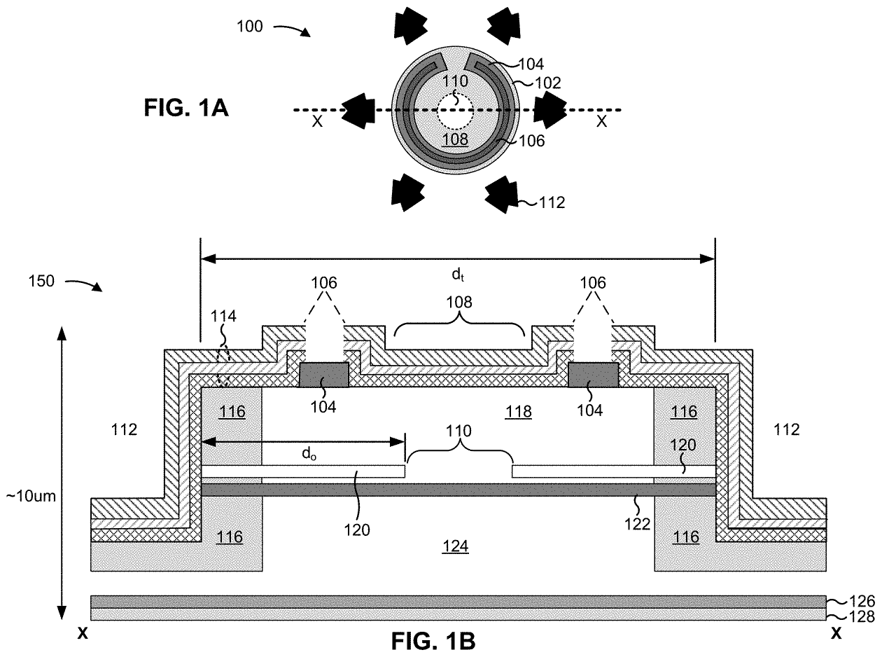

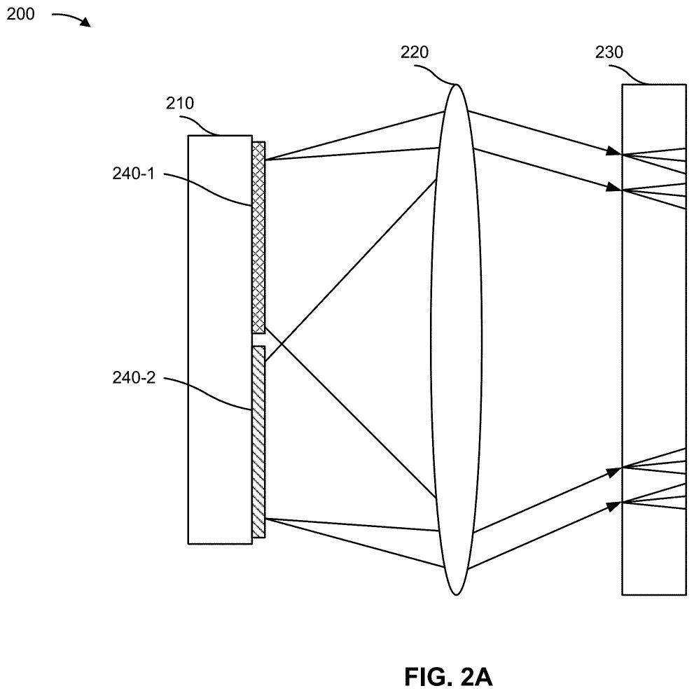

FIGS. 1A and 1B are diagrams depicting a top-view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices, such as a VCSEL associated with emitting structured light, as described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). A first area of ohmic metal layer 104 covered by a protective layer (e.g., a dielectric layer or a passivation layer) of emitter 100 and a second area of ohmic metal layer 104 is exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 may include a protective layer in which via 106 is formed (e.g., etched). The second area of ohmic metal layer 104 that is exposed by via 106 (e.g., a shape of the second area may be a result of the shape of via 106) while the first area of ohmic metal layer 104 is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits light via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and may be limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as a gold-germanium-nickel (AuGeNi) layer, a palladium-germanium-gold (PdGeAu) layer, or the like.

Substrate layer 126 may include a base substrate layer upon which epitaxial layers are grown. For example, substrate layer 126 may include a semiconductor layer, such as a gallium-arsenide (GaAs) layer, an indium-phosphide (InP) layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an aluminum-oxide (Al₂O₃) layer formed as a result of oxidation of an aluminum-arsenide (AlAs) or aluminum-gallium-arsenide (AlGaAs) layer. Trenches 112 may include openings that allow oxygen to access the epitaxial layer from which oxidation layer 120 is formed.

Current confinement aperture 110 may include an optically active aperture defined by oxidation layer 120. A size of current confinement aperture 110 may range, for example, from approximately 4 micrometers (μm) to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a silicon-dioxide (SiO2) layer, a silicon-nitride (Si3N4) layer, an aluminum-oxide (Al2O3) layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a titanium (Ti) and gold (Au) layer, a Ti and platinum (Pt) layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms. Selection of a particular type of ohmic metal layer 104 may depend on the architecture of the emitters. Ohmic metal layer 104 may provide ohmic contact between a metal and a semiconductor and/or may provide a non-rectifying electrical junction and/or may provide a low-resistance contact.

In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

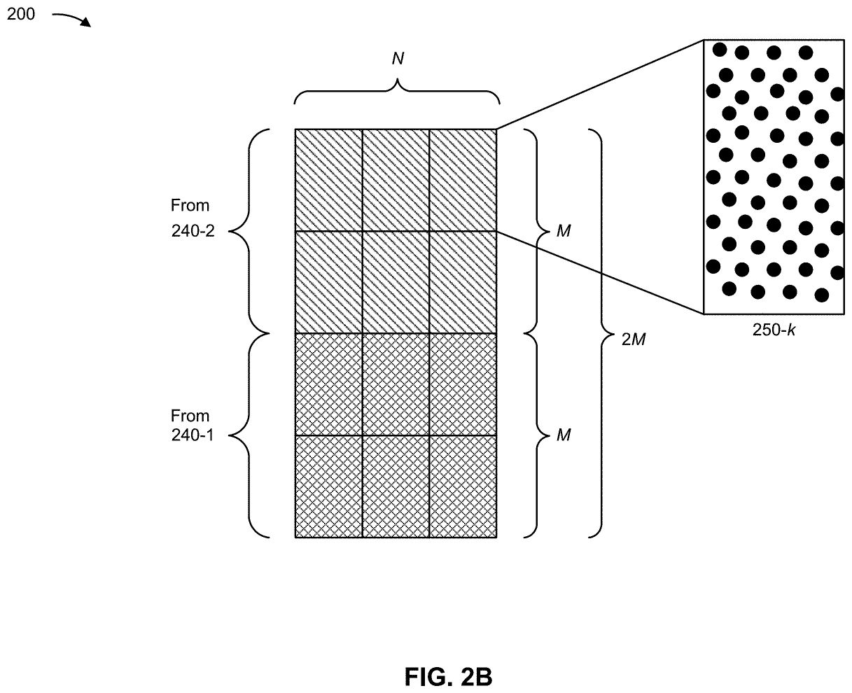

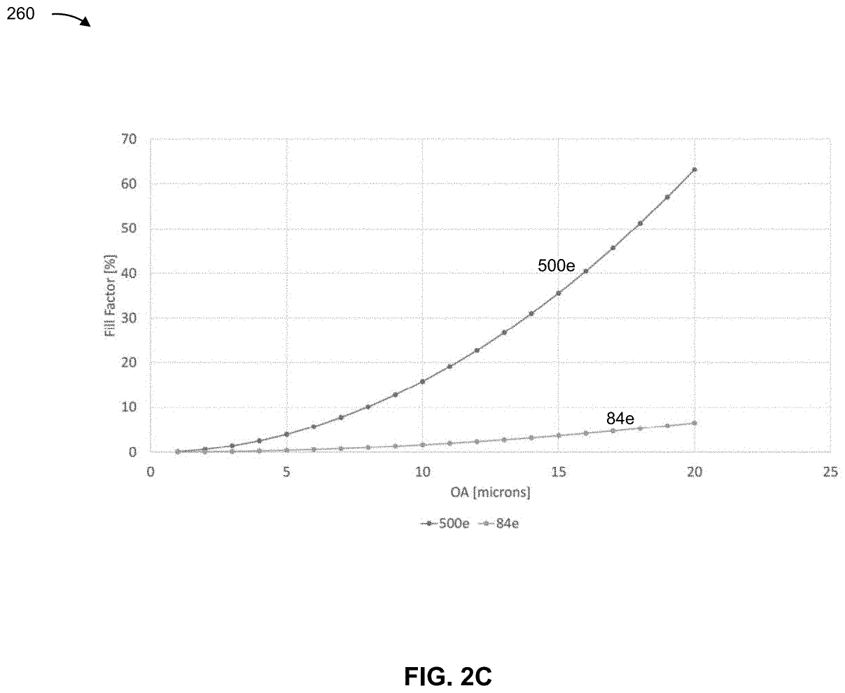

FIGS. 2A-2C are diagrams of an example optical device 200. As shown in FIG. 2A, optical device 200 may include an emitter 210, a lens 220, and a diffractive optical element (DOE) 230.

In some implementations, emitter 210 may include a vertical emitting type of emitter, such as a VCSEL. For example, emitter 210 may be a VCSEL configured to emit structured light from one or more emission zones 240. In this case, the emitter 210 includes a first emission zone 240-1 and a second emission zone 240-2 provided on a single substrate. In this way, optical device 200 reduces an alignment complexity relative to aligning multiple emitters 210, each with a corresponding emission zone 240, to each other and/or to lens 220, DOE 230, and/or a target.

An emission zone 240-1 may be an active area of a VCSEL or VCSEL array, such as an approximately 640 μm×630 μm active area, configured to output structured light with a particular quantity and/or pattern of dots. For example, each emission zone 240 may be an array of emitters of a VCSEL. In this case, the array of emitters may be arranged in a grid (e.g., a rectangular packing pattern, a square packing pattern, a hexagonal packing grid, a non-uniform packing pattern, such as a set of differently shaped clusters of dots), such as a grid of, for example, 7×12 emitters for a total of 84 emitters per emission zone 240. In this case, with two emission zones 240, optical device 200 is associated with an output of 168 dots of structured light toward lens 220. Although some implementations are described in terms of a particular quantity or arrangement of emitters, other quantities or arrangements of emitters are contemplated.

In some implementations, lens 220 may include a collimating lens or other collimating element. For example, lens 220 may be a single collimating lens aligned to the emission zones 240 of the emitter 210. In this case, lens 220 may collimate the structured light (e.g., the 168 dots of structured light) emitted from the emission zones 240 toward the DOE 230 and a target or screen. In this way, optical device 200 reduces alignment complexity relative to providing multiple lenses 220 aligned to respective emission zones 240. In some implementations, lens 220 may be associated with a particular field of interest (FOI) with a particular aspect ratio. For example, lens 220 may direct the structured light toward DOE 230, such that a projection of the structured light has an FOI of approximately 48 degrees×62 degrees and/or an aspect ratio of approximately 3:4. In some implementations, optical device 200 may be associated with a diagonal FOI of approximately 75 degrees.

In some implementations, DOE 230 may include a tiling DOE. For example, DOE 230 may be an M×N fan-out DOE, where M represents a quantity of vertical projections of an output of each emission zone 240 and N represents a quantity of horizontal projections of an output of each emission zone 240. In other words, as shown in FIG. 2B, each emission zone 240 may output a projection 250 of structured light (e.g., a set of dots), and tiles of DOE 230 may multiply instances of the projection 250 of structured light (e.g., into a set of projections 250-1 through 250-k). For example, there is a set of M×N projections 250 from emission zone 240-2 and a set of M×N projections 250 from emission zone 240-1. In some implementations, DOE 230 may be a M′×N′ DOE providing M×N projections 250 (where M<M′ or N<N′). For example, DOE 230 may be a 3×3 DOE, such that there are 9 projections 250 from emission zone 240-1 and 9 projections 250 from emission zone 240-2. However, extinction of orders in the 3×3 DOE result in a 2×3 projection from each emission zone 240, as shown, rather than a 3×3 projection.

In some implementations, DOE 230 and optical device 200 may be configured to output greater than a threshold quantity of dots, such as greater than 500 dots from each emission zone 240 (e.g., greater than 1000 dots total). For example, when there are two emission zones 240 and DOE 230 is a 2×3 tiling DOE, optical device 200 may output 12 projections 250 of structured light. Further, if each emission zone 240 includes, for example, 84 emitters configured to output 84 dots, optical device 200 projects, in total, 504 dots from emission zone 240-1 to a first set of 6 projections 250 and 504 dots from emission zone 240-2 to a second set of 6 projection 250 for a total of 1008 dots of structured light across 12 projection 250. In this way, by using a tiling DOE to project multiple projections of each emission zone, a quantity of emitters that are included in each emission zone (e.g., to achieve a particular total quantity of dots of structured light) can be reduced relative to other optical devices that lack a tiling DOE. For example, optical device 200 may have a FOI of 16×15.5 degrees for each emission zone, which may be a reduction from a 48×31 degree FOI for another optical device that lacks a tiling DOE.

In some implementations, optical device 200 may suppress one or more diffraction orders of DOE 230. For example, a 2×3 tiling DOE used for DOE 230 may be configured as a 3×3 tiling DOE with 3 of the diffraction orders suppressed to avoid cross-talk or overlap between projections 250 associated with emission zone 240-1 and emission zone 240-2. In other words, a first 3 projections 250 of emission zone 240-1 may be suppressed to avoid overlap with a second 3 projections 250 of emission zone 240-2. In some implementations, another configuration of a tiling DOE may be possible for DOE 230, such as a 1×3 DOE, a 2×1 DOE, a 2×2 DOE, a 3×5 DOE, a 5×5 DOE, or another other arrangement of a tiling DOE.

In some implementations, optical device 200 may project the structured light with a fill factor less than a threshold. For example, using a 2×3 tiling DOE aligned to two emission zones 240, each including 84 emitters, optical device 200 may achieve a fill factor of less than approximately 10%. In this way, by using a tiling DOE aligned to lens 220 and emitter 210, optical device 200 enables a reduced fill factor relative to other optical devices that do not include a tiling DOE. For example, in another configuration, where a collimating lens projects emission zones 240 directly to a target (e.g., which may be approximately 50 centimeters (cm) from optical device 200), optical apertures (OAs) of between 5 μm and 15 μm can result in a fill factor of between approximately 10% and approximately 35%. For example, as shown in FIG. 2C and by reference number 260, an optical device with 500 emitters in each emission zone (e.g., to achieve 1000 dots of structured light total) has a fill factor of 35% with an OA of 15 μm. In contrast, the optical device 200 (e.g., with 84 emitters in each emission zone to achieve greater than 1000 dots of structured light total) achieves a fill factor of less than 5% at an OA of 15 μm. Accordingly, to achieve a fill factor of less than approximately 10%, other optical devices may have to reduce an optical aperture size, which reduces available optical power. In contrast, optical device 200, with a less than 20 μm optical aperture used with a tiling DOE, can have a fill factor of less than approximately 10%, thereby enabling increased available optical power for optical device 200 relative to other optical devices. Furthermore, use of a tiling DOE enables an increase in focal length (e.g., effective focal length (EFL)) and/or magnification at lens 220, thereby reducing aberrations introduced by lens 220. For example, a 5% VCSEL fill factor of emission zones 240 may result in an 8% dot fill factor for projections 250 as a result of optical aberrations at, for example, lens 220.

In some implementations, projections 250 (which may be referred to as “projection zones”) may be arranged without a gap or without overlap. In other words, a pattern of dots in a first projection zone may continue into a second projection zone without a gap and non-overlapping, which results in the pattern of dots not having any interruption between discrete dots of different projection zones. Additionally, or alternatively, the 12 projection zones may be arranged with less than a threshold gap or overlap (e.g., a gap or overlap may be less than 10% a size of a projection zone or less than 50% a size of a spacing between dots within a pattern of dots).

As indicated above, FIGS. 2A-2C are provided as an example. Other examples may differ from what is described with regard to FIGS. 2A-2C.

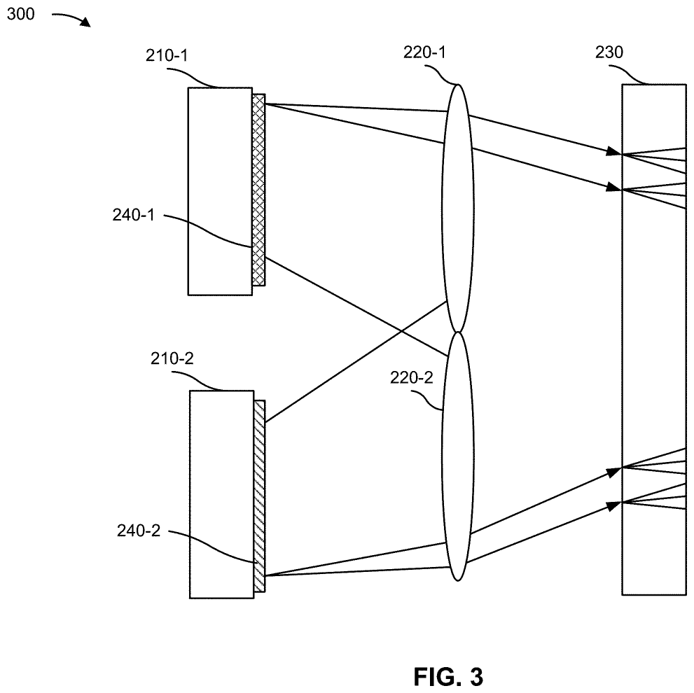

FIG. 3 is a diagram of an example optical device 300. As shown in FIG. 3, optical device 300 may include a set of emitters 210, a set of lenses 220, and a DOE 230.

In some implementations, optical device 300 may include a first emitter 210-1 and a second emitter 210-2. In this case, each emitter 210 includes a single corresponding emission zone 240. In this way, optical device 300 enables use of VCSELs with a single emission zone, which may improve deployment flexibility relative to using VCSELs with multiple emission zones. In some implementations, the set of emitters 210 is aligned to the set of lenses 220. For example, a first lens 220-1 is aligned to the set of emitters 210 and a second lens 220-2 is aligned to the set of emitters 210. In this case, a tiling DOE 230 is aligned to the set of lenses 220 to project a set of projections toward a target.

As indicated above, FIG. 3 is provided as an example. Other examples may differ from what is described with regard to FIG. 3. The number and arrangement of devices shown in FIG. 3 are provided as an example.

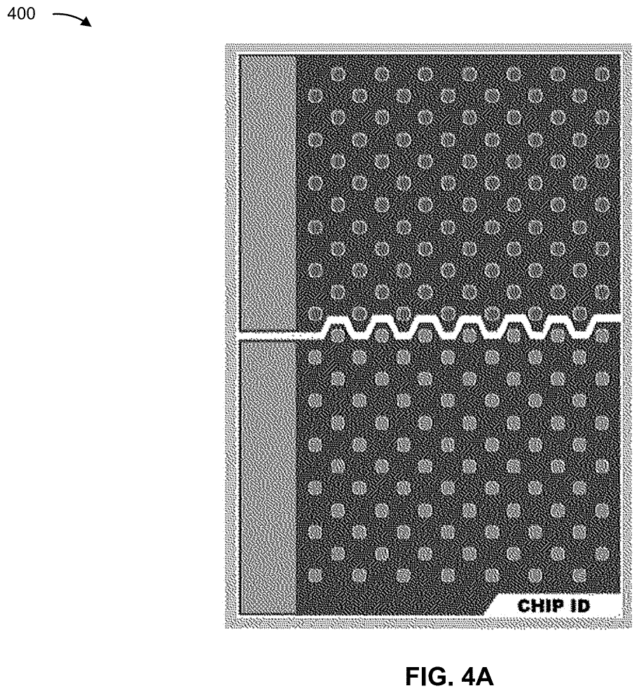

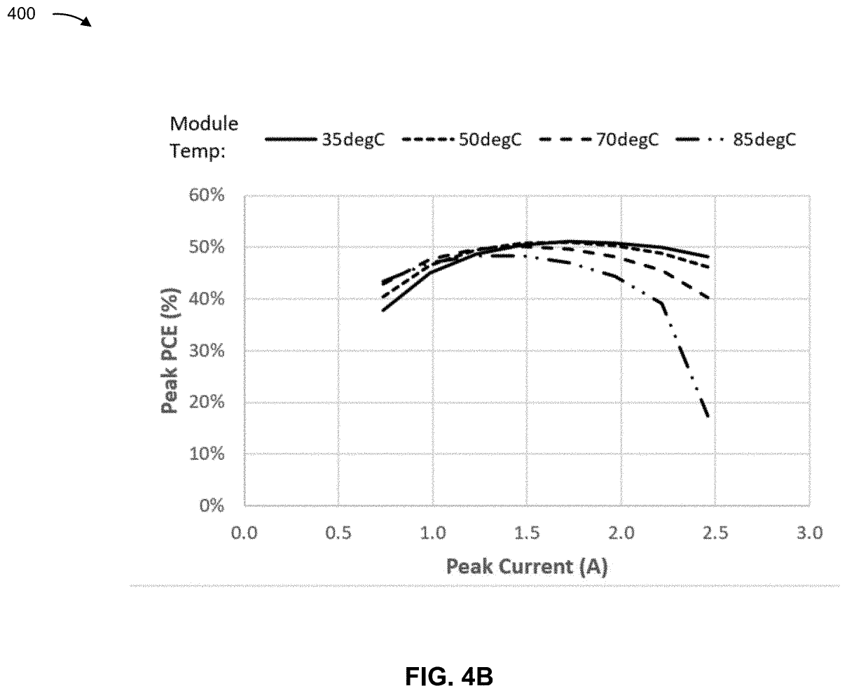

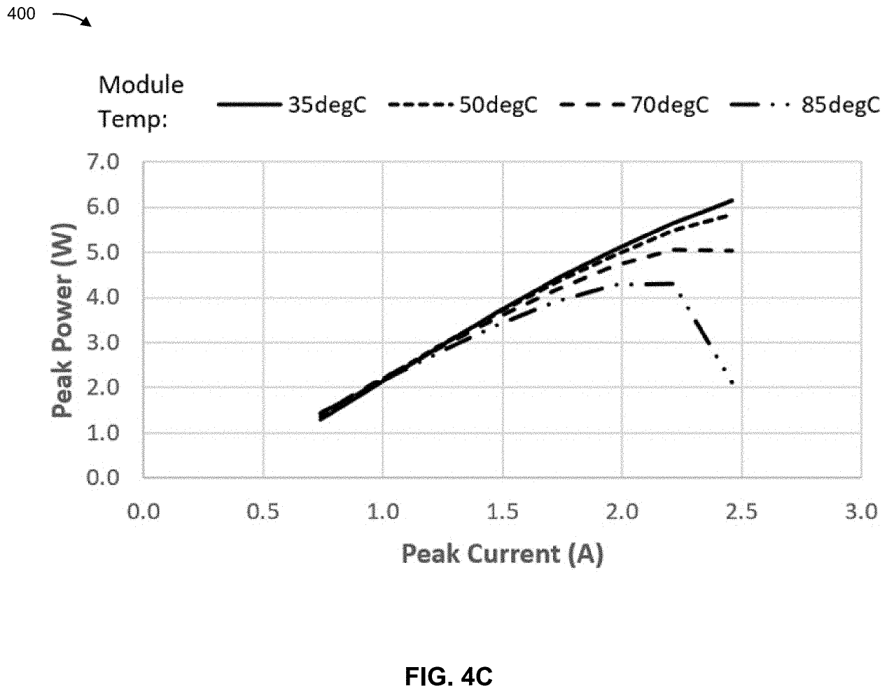

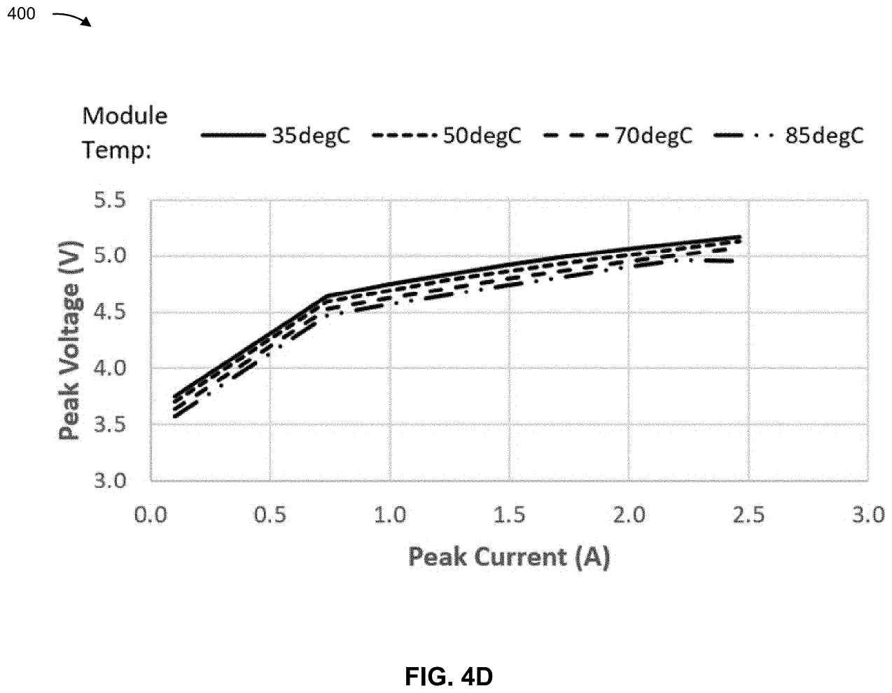

FIGS. 4A-4D are diagrams of an example of electro-optical characteristics associated with an optical device 400. As shown in FIG. 4A, emission zones 410-1 and 410-2 of the optical device 400 may correspond to the emission zones 240-1 and 240-2 of the optical device 200 and the emitter 210. For example, the optical device 400 may be associated with a three junction common anode configuration (e.g., with separate cathodes) for a VCSEL array of multiple emitters arranged in multiple emission zones (e.g., a 2-zone VCSEL chip or a 2-channel driver chip). The emission zones 410-1 and 410-2 may total approximately 1380×760 μm (with each emission zone 410 having an active area of approximately 612 μm×604 μm) and include 84 emitters per zone (e.g., 168 total emitters) in a hexagonal packing pattern. A die size to provide emission zones 410-1 and 410-2 may be approximately 1 square millimeter (mm²).

FIGS. 4B-4D shows the electro-optical characteristics (e.g., power conversion efficiency (PCE) and current-power (L-I) characteristics) for the optical device 400 when driven at 5.0 watts (W) at 2.0 amps (A) and 5.2 volts (V) for 65 milliwatts per emitter (mW/e) and 10 milliwatts per dot (mW/dot). In some implementations, the optical device 400 may be associated with a nanosecond range pulse, such as a pulsing frequency of approximately 100 megahertz (MHz) or a pulsing frequency in a range of 1 MHz to 1000 MHz, among other examples. As shown in FIG. 4B, the optical device 400 may achieve a peak PCE % in a range of approximately 45% to approximately 55% for temperatures of between 35 degrees Celsius (C) and 85 degrees C. and peak currents in a range of 0.75 to 2.5 A. The optical device 400 may achieve a peak power in a range of 1.5 W to 6.0 W for the aforementioned range of peak currents. The optical device 400 may achieve a peak voltage in a range of 4 V to 5.5 V for the aforementioned range of peak currents.

As indicated above, FIGS. 4A-4D are provided as an example. Other examples may differ from what is described with regard to FIGS. 4A-4D.

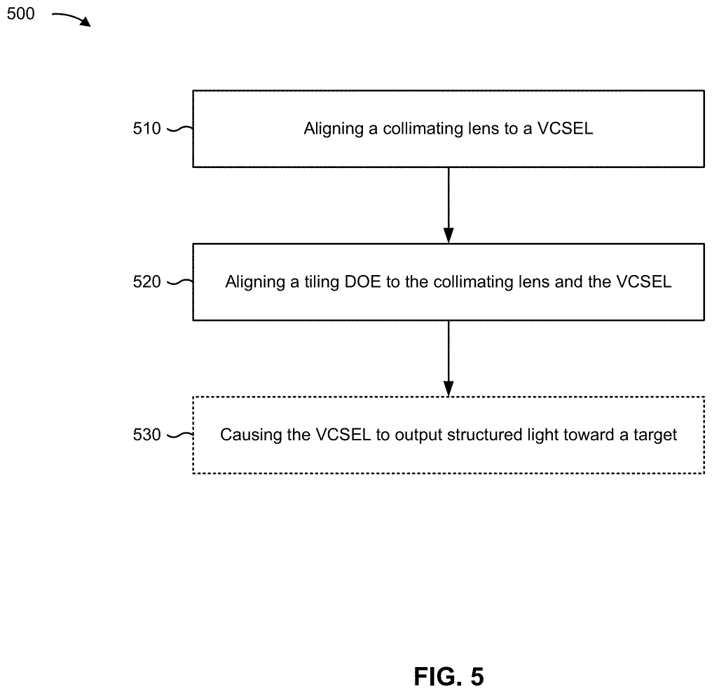

FIG. 5 is a flowchart of an example process 500 associated with using an optical device described herein. In some implementations, one or more process blocks of FIG. 5 are performed by controller.

As shown in FIG. 5, process 500 may include aligning a collimating lens to a VCSEL (block 510). For example, a controller may align one or more collimating lenses to a single VCSEL with multiple emission zones or to multiple VCSELs, each with one or more emission zones, as described above.

As further shown in FIG. 5, process 500 may include aligning a tiling DOE to the collimating lens and the VCSEL (block 520). For example, the controller may align an M×N tiling DOE to the one or more collimating lenses and the one or VCSELs to enable the tiling DOE to output k projections of structured light, where k=M×N×z and z represents a quantity of emission zones of the one or more VCSELs, as described above. In this case, the tiling DOE outputs a quantity z of M×N projections of emitted light from the VCSEL. A total quantity of dots projected is e×z×M×N, where e is a quantity of discrete emitters in each emission zone. In some implementations, each emitter emits a single dot. In some implementations, each emitter may emit multiple dots or may be associated with an optic to cause a single dot to be emitted to the one or more collimating lenses as multiple dots.

As shown in FIG. 5, process 500 may include causing the VCSEL to output structured light toward a target (block 530). For example, after assembling an optical device by aligning the tiling DOE to the collimating lens and the VCSEL, the controller may cause the VCSEL to output structured light toward a target, as described above.

Process 500 may include additional implementations, such as any single implementation or any combination of implementations described herein.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical device, comprising:
a two-zone vertical cavity surface emitting laser (VCSEL) with a set of emission zones configured to emit structured light forming a set of dots;
a single-element collimating lens aligned to the two-zone VCSEL; and
a tiling diffractive optical element (DOE) aligned to the single-element collimating lens,
wherein the tiling DOE comprises a set of tile segments aligned to the set of emission zones, and
wherein a tile segment, of the set of tile segments, is configured to project, from the set of emission zones toward portions of a target, the structured light forming the set of dots.

2. The optical device of claim 1, wherein the set of tile segments is arranged in an M×N grid of tile segments forming a first M×N projection of structured light from a first emission zone, of the set of emission zones, and forming a second M×N projection of structured light from a second emission zone.

3. The optical device of claim 2, wherein M>2 and N>2.

4. The optical device of claim 2, wherein M=2 and N=3.

5. The optical device of claim 2, wherein a total quantity of dots of structured light is e×z×M×N, wherein z represents a quantity of emission zones and e represents a quantity of emitters in each emission zone.

6. The optical device of claim 1, wherein the set of tile segments is arranged in an M′×N′ grid of tile segments forming a first M×N projection of structured light from a first emission zone, of the set of emission zones, and forming a second M×N projection of the structured light from a second emission zone, wherein extinction orders associated with the structured light and the set of tile segments are associated with at least one of M<M′ or N<N′.

7. The optical device of claim 1, wherein the set of tile segments are associated with a set of non-overlapping projections of the structured light.

8. The optical device of claim 7, wherein a gap between a first projection associated with a first tile segment, of the set of tile segments, and a second projection associated with a second tile segment, of the set of tile segments, is approximately the same as a gap between discrete dots within the set of tile segments.

9. The optical device of claim 1, wherein the set of dots of the structured light is arranged in at least one of:
a hexagonal packing pattern,
a square packing pattern,
a non-uniform packing pattern.

10. The optical device of claim 1, wherein a fill factor of a projection of the set of dots of the structured light is less than 10%.

11. An optical device, comprising:
a first vertical cavity surface emitting laser (VCSEL) with a first emission zone configured to emit first structured light forming a first set of dots;
a second VCSEL with a second emission zone configured to emit second structured light forming a second set of dots;
a single-element collimating lens aligned to the first VCSEL and the second VCSEL; and
a tiling diffractive optical element (DOE) aligned to the single-element collimating lens,
wherein the tiling DOE comprises a set of tile segments aligned to the first emission zone to form a first set of projections of the first set of dots and aligned to the second emission zone to form a second set of projections of the second set of dots.

12. The optical device of claim 11, wherein a quantity of dots in the first set of projections and the second set of projections is greater than 1000 dots.

13. The optical device of claim 11, wherein a field of illumination covered by the first set of projections and the second set of projections is at least 40 degrees by 60 degrees.

14. The optical device of claim 11, wherein a field of illumination of each tile segment, of the set of tile segments, is at less than 20 degrees by 20 degrees.

15. The optical device of claim 11, wherein a field of illumination covered by the first set of projections and the second set of projections has an aspect ratio of 3:4.

16. The optical device of claim 11, wherein an optical aperture of the optical device is less than 20 micrometers.

17. The optical device of claim 11, wherein an optical power of each emission zone is between 3 and 7 watts when the optical device is driven at 2 amps and 5.2 volts.

18. An optical device, comprising:
at least one vertical cavity surface emitting laser (VCSEL),
wherein the at least one VCSEL comprises a set of emission zones,
wherein an emission zone, of the set of emission zones, is configured to emit structured light forming a set of dots;
at least one single-element collimating lens aligned to the set of emission zones of the at least one VCSEL; and
a tiling diffractive optical element (DOE) aligned to the at least one single-element collimating lens,
wherein the tiling DOE comprises a set of tile segments aligned to the set of emission zones, and
wherein a tile segment, of the set of tile segments, is configured to project the structured light forming the sets of dots from the set of emission zones toward portions of a target.

19. The optical device of claim 18, wherein a quantity of emission zones is 2 or more emission zones.

20. The optical device of claim 18, wherein a quantity of tile segments is 6 or more tile segments.
